(19) United States
(12) Patent Application Publication
(10) Pub. No.: US 2024/0021921 A1
(43) Pub. Date: Jan. 18, 2024

(54) BATTERY LOW-TEMPERATURE HEATING AND CHARGING SYSTEM, VEHICLE-MOUNTED AIR CONDITIONING SYSTEM AND VEHICLE

(71) Applicant: HUIZHOU ROYPOW TECHNOLOGY CO., LTD, Huizhou (CN)

(72) Inventor: Fangzheng KOU, Huizhou (CN)

(21) Appl. No.: 18/329,811

(22) Filed: Jun. 6, 2023

(30) Foreign Application Priority Data
Jul. 18, 2022 (CN) 202221846127.1

(51) Int. Cl. H01M 10/663; H01M 10/615; H01M 10/625; B60H 1/00; H01M 10/48; H01M 10/44

(52) U.S. Cl. CPC H01M 10/663; H01M 10/615; H01M 10/625; B60H 1/00278; H01M 10/486; H01M 10/443; H01M 2220/20; G01R 31/382

(57) ABSTRACT

The present disclosure relates to a battery low-temperature heating and charging system, a vehicle-mounted air conditioning system and a vehicle. The battery low-temperature heating and charging system includes: a heating module, a switching module, a battery module, a power generation module, a temperature sensor, a current sensor, and a battery management system. The battery management system is respectively connected to the temperature sensor, the current sensor, the switching module and the power generation module. The current sensor is arranged between the battery module and the power generation module, and the heating module is connected to the switching module.

### CROSS-REFERENCE TO RELATED APPLICATIONS

This application claims priority to Chinese patent application No. 202221846127.1 filed with the Chinese Patent Office on Jul. 18, 2022, entitled “BATTERY LOW-TEMPERATURE HEATING AND CHARGING SYSTEM, VEHICLE-MOUNTED AIR CONDITIONING SYSTEM AND VEHICLE”, the entire content of which is incorporated by reference.

### TECHNICAL FIELD

The present application relates to the field of battery low-temperature charging technology, and in particular, to a battery low-temperature heating and charging system, a vehicle-mounted air-conditioning system and a vehicle.

### BACKGROUND

With the popularity of electric vehicles, the performance of the battery such as charging and safety becomes particularly important, but in the conventional art, as the battery is more sensitive to temperature changes under a low temperature condition, it is generally not allowed to be charged in a low temperature environment, thus causing it not to meet the needs of practical applications.

Therefore, it is necessary to consider heating the power battery in the low temperature environment, so as to increase its temperature, improve the charging effect, give full play to the capability of the power battery pack, and improve the safety, in order to further improve the overall performance of the electric vehicles.

In the traditional technology, the implementation scheme of battery heating has low precision and poor heating effect.

### SUMMARY

Based on this, it is necessary to provide a battery low-temperature heating and charging system, a vehicle-mounted air-conditioning system and a vehicle in response to the above technical problems.

In a first aspect, a battery low-temperature heating and charging system is provided, including: a heating module; a switching module having a first terminal connected to the heating module; a battery module disposed close to the heating module, and having a first terminal connected to a second terminal of the switching module; a power generation module having a first terminal connected to the second terminal of the switching module; a temperature sensor configured to acquire a temperature of the battery module; a current sensor having a first terminal connected to a second terminal of the power generation module, and a second terminal connected to a second terminal of the battery module, the current sensor being configured to detect current supplied from the power generation module to the battery module; and a battery management system having a first terminal connected to a third terminal of the power generation module, a second terminal connected to a third terminal of the current sensor, a third terminal connected to the temperature sensor, and a fourth terminal connected to a third terminal of the switching module. The power generation module has a fourth terminal configured to connect a power module.

In an embodiment, the battery management system includes: a first comparison module having a first terminal connected to the third terminal of the current sensor, and a second terminal configured to receive a first reference electrical signal used as an electrical signal representing a threshold current; a second comparison module having a first terminal connected to the temperature sensor, and a second terminal configured to receive a second reference electrical signal used as an electrical signal representing a first threshold temperature or a second threshold temperature; and a control module having a first terminal connected to a third terminal of the first comparison module, a second terminal connected to a third terminal of the second comparison module, a third terminal connected to the third terminal of the power generation module, and a fourth terminal connected to the third terminal of the switching module.

In an embodiment, the control module includes: a voltage adjustment module having a first terminal connected to the third terminal of the power generation module; and a heating control module having a first terminal connected to the third terminal of the first comparison module, a second terminal connected to the third terminal of the second comparison module, a third terminal connected to a second terminal of the voltage adjustment module, and a fourth terminal connected to the third terminal of the switching module.

In an embodiment, the heating module includes a PTC heating plate.

In an embodiment, the heating module completely covers at least one end face of the battery module.

In an embodiment, the current sensor includes a shunt.

In an embodiment, the battery module includes a lithium battery.

In an embodiment, the battery low-temperature heating and charging system further includes: a voltage sensor having a first terminal connected to the fourth terminal of the power generation module. The battery management system further includes a third comparison module having a first terminal connected to a second terminal of the voltage sensor, a second terminal connected to a fifth terminal of the control module, and a third terminal configured to receive a third reference electrical signal used as an electrical signal representing a threshold voltage.

In a second aspect, a vehicle-mounted air conditioning system is provided, including: an air conditioner body mounted on a vehicle body; and a battery low-temperature heating and charging system mounted on the vehicle body. The battery module is connected to the air conditioner body.

In a third aspect, a vehicle is provided, including: a vehicle body, equipped with a power module; and a battery low-temperature heating and charging system mounted on the vehicle body.

The above-mentioned battery low-temperature heating and charging system switches on the switching module when the temperature of the battery module is lower than the first threshold temperature, the battery module supplies power to the heating module through the switching module, and the heating module is powered to heat the battery module so that the temperature of the battery module is increased. Meanwhile, the current acquired by the current sensor is detected to determine whether the power generation module supplies power to the battery module, and the battery management system controls, based on the determination, the output voltage of the power generation module so that the output voltage is limited to be beyond the voltage of the battery module, thus avoiding a poor effect caused by influence of a low temperature on the charging efficiency, and avoiding energy waste. When the temperature of the battery module is greater than the second threshold temperature, the battery management system switches off the switching module and thus powers off the heating module, thereby avoiding safety issues such as battery fire caused by continuous heating.

### BRIEF DESCRIPTION OF THE DRAWINGS

In order to more clearly illustrate the technical solutions in the embodiments of the present application or in the traditional technology, the following briefly introduces the accompanying drawings that are used in the description of the embodiments or the traditional technology. Apparently, the accompanying drawings in the following description are only some of the embodiments of the present application, for those of ordinary skill in the art, other drawings can also be obtained according to these accompanying drawings without any creative effort.

FIG. 1 is a schematic diagram illustrating an application environment of a battery low-temperature heating and charging system according to an embodiment of the present application.

FIG. 2 is a schematic diagram illustrating a configuration of the battery low-temperature heating and charging system according to an embodiment of the present application.

FIG. 3 is a schematic diagram illustrating a configuration of the battery low-temperature heating and charging system according to another embodiment of the present application.

FIG. 4 is a schematic diagram illustrating a configuration of the battery low-temperature heating and charging system according to a further embodiment of the present application.

FIG. 5 is a schematic diagram illustrating a configuration of the battery low-temperature heating and charging system according to a further embodiment of the present application.

FIG. 6 is a schematic diagram showing the position of the heating module according to an embodiment of the present application.

FIG. 7 is a schematic diagram showing the connection between the battery low-temperature heating and charging system and the power module according to an embodiment of the present application.

### DETAILED DESCRIPTION

In order to facilitate understanding of the present application, the present application will be described more fully below with reference to the relevant accompanying drawings. Embodiments of the present application are presented in the accompanying drawings. However, the present application may be implemented in many different forms and is not limited to the embodiments described herein. Rather, these embodiments are provided for the purpose of making the present application more thorough and comprehensive.

Unless otherwise defined, all technical and scientific terms used herein have the same meaning as commonly understood by those skilled in the technical field to which the present application belongs. The terms used herein in the specification of the application are for the purpose of describing specific embodiments only, and are not intended to limit the application.

It will be understood that the terms “first”, “second”, etc. used in this application may be used herein to describe various elements, but these elements are not limited by these terms. These terms are only used to distinguish the first element from another element.

It should be noted that when an element is referred to as being “connected to” another element, it can be directly connected to another element or connected to another element through a intervening element. In addition, the “connected” in the following embodiments should be understood as “electrically connected”, “connected by communication”, etc. if there is transmission of electrical signals or data between the objects to be connected.

As used herein, the singular forms “a”, “an” and “the” may also include the plural forms, unless the context clearly indicates otherwise. It should also be understood that the terms “includes/comprises” or “has” etc. designate the presence of stated features, integers, steps, operations, components, parts or combinations thereof, but do not preclude the possibility of the presence or addition of one or more other features, integers, steps, operations, components, parts or combinations thereof.

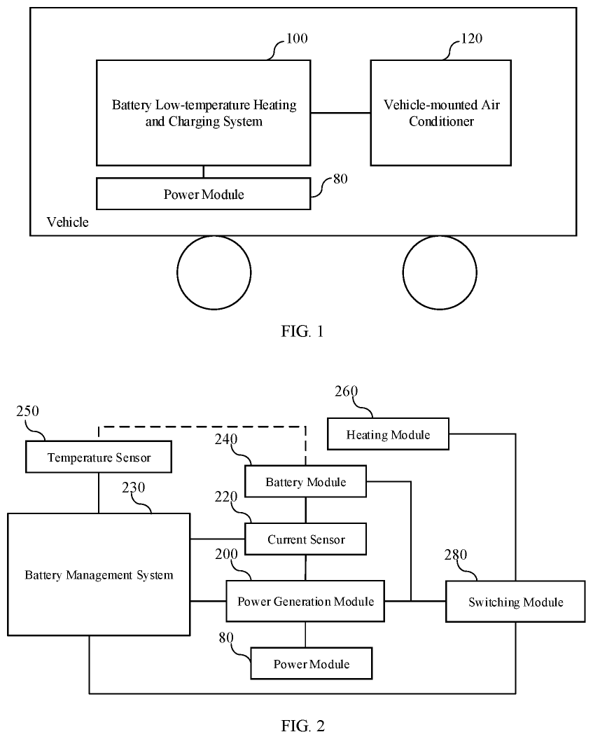

A battery low-temperature heating and charging system provided in the embodiment of the present application can be applied to the application environment shown in FIG. 1. The battery low-temperature heating and charging system 100 is connected to a power module 80, and the battery low-temperature heating and charging system 100 converts the kinetic energy provided by the power module 80 into electrical energy and stores it in the system. The battery low-temperature heating and charging system may also be connected to a vehicle-mounted air conditioner 120, and the battery low-temperature heating and charging system may deliver the stored electrical energy to the vehicle-mounted air conditioner 120. The entire structure is built into the interior of the vehicle. The power module 80 may include but is not limited to an engine.

In an embodiment, as shown in FIG. 2, a battery low-temperature heating and charging system is provided, including a heating module 260, a switching module 280, a battery module 240, a power generation module 200, a temperature sensor 250, a current sensor 220, and a battery management system 230.

A first terminal of the switching module 280 is connected to the heating module 260, a first terminal of the battery module 240 is connected to a second terminal of the switching module 280, and a first terminal of the power generation module 200 is connected to the second terminal of the switching module 280. The temperature sensor 250 is configured to acquire a temperature of the battery module 240. A first terminal of the current sensor 220 is connected to a second terminal of the power generation module 200, and a second terminal of the current sensor 220 is connected to a second terminal of the battery module 240. A first terminal of the battery management system 230 is connected to a third terminal of the power generation module 200, a second terminal of the battery management system 230 is connected to a third terminal of the current sensor 220, a third terminal of the battery management system 230 is connected to the temperature sensor 250, a fourth terminal of the battery management system 230 is connected to a third terminal of the switching module 280.

The switching module 280 is a circuit that can be in an on-state or off-state. For example, the switching module 280 may include a relay, a controlled switch, etc. In the on-state, the power supply paths between the heating module 260 and the power generation module 200 or the battery module 240 can be turned on, and in the off-state, the power supply to the heating module 260 can be turned off.

Specifically, the battery management system 230 detects the temperature of the battery module 240 in real time through the temperature sensor 250, and can obtain the results of the comparison between the temperature of the battery module 240 and a first threshold temperature, and between the temperature of the battery module 240 and a second threshold temperature. The second threshold temperature is greater than the first threshold temperature. For example, when the battery module 240 is a lithium battery to be charged at a low temperature, the first threshold temperature may be set to 5° C., and the second threshold temperature may be set to 15° C. When the temperature of the battery module 240 is lower than the first threshold temperature, the battery management system 230 can detect whether the power generation module 200 charges the battery module 240 through the current sensor 220 connected between the battery module 240 and the power generation module 200. The battery management system 230 adjusts the voltage of the power generation module 200 in real time based on the above temperature and the detection of current.

Specifically, the battery management system 230 switches on the switching module 280 when the temperature of the battery module 240 is less than the first threshold temperature, and the battery module 240 supplies power to the heating module 260 through the switching module 280. The heating module 260 is powered to heat the battery module 240 so that the temperature of the battery module 240 is increased. During this process, if the battery management system 230 detects that the current acquired by the current sensor 220 is not zero, it means that the power generation module 200 supplies power to the battery module 240. At this time, the charging efficiency is affected by the low temperature and the effect is poor. The battery management system 230 controls the output voltage of the power generation module 200 so that the output voltage is limited to be beyond the voltage of the battery module 240, thus avoiding the power generation module 200 to supply power to the battery module 240 and thus avoiding energy waste. And in the heating control process performed when the temperature of the battery module 240 is lower than the first temperature threshold, the output voltage of the power generation module 200 is gradually increased, and the output voltage is always less than or equal to the voltage of the battery module 240 during this process. When the temperature of the battery module 240 is greater than or equal to the first threshold temperature and less than the second threshold temperature, the battery management system 230 increases the output voltage of the power generation module 200 to be greater than the voltage of the battery module 240. At this time, the power generation module charges the battery module 240 and outputs current to the heating module 260, and the heating module 260 is powered by the power generation module 200 to generate heat. When the temperature of the battery module 240 is greater than the second temperature threshold, the battery management system 230 switches off the switching module 280 to power off the heating module 260.

The battery low-temperature heating and charging system detects the temperature of the battery module 240 in real time through the built-in temperature sensor 250, and detects whether the power generation module 200 charges the battery module 240 at the low temperature in real time through the current sensor 220 connected between the battery module 240 and the power generation module 200. Based on the above detected information, the battery management system 230 adjusts the voltage of the power generation module 200 and controls the on-off of the switching module 280 in real time, thus controlling the heating module 260 to heat the battery module 240, and avoiding the phenomenon of charging the battery module 240 when the charging temperature is not reached, thus avoiding energy waste due to a low efficiency of charging at a low temperature. When the temperature of the battery module 240 exceeds the second threshold temperature, the battery management system 230 controls the switching module 280 to switch off, thereby disconnecting the power supply to the heating module 260, avoiding the safety issue caused by the battery fire due to continuous heating, and further improving the reliability of the battery module 240.

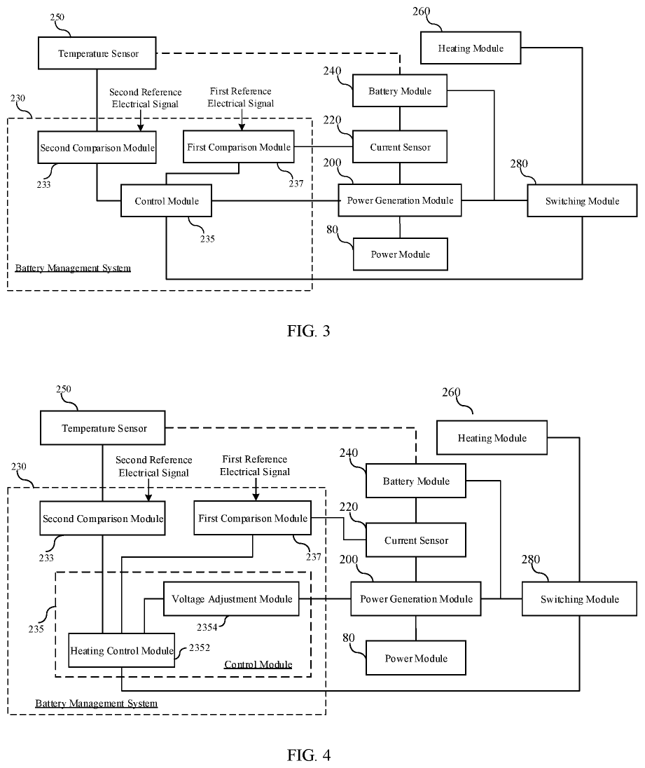

In an embodiment, as shown in FIG. 3, the battery management system 230 includes a first comparison module 237, a second comparison module 233 and a control module 235. A first terminal of the first comparison module 237 is connected to the third terminal of the current sensor 220, and a second terminal of the first comparison module 237 is configured to receive a first reference electrical signal. The first reference electrical signal is used as an electrical signal representing a current value of zero. A first terminal of the second comparison module 233 is connected to the temperature sensor 250, and a second terminal of the second comparison module is configured to receive a second reference electrical signal. The second reference electrical signal is an electrical signal representing a low temperature threshold. A first terminal of the control module 235 is connected to a third terminal of the first comparison module 237, a second terminal of the control module 235 is connected to a third terminal of the second comparison module 233, a third terminal of the control module 235 is connected to the power generation module 200, and a fourth terminal of the control module 235 is connected to the third terminal of the switching module 280.

Each of the first comparison module 237 and the second comparison module 233 may be a current comparator or a temperature comparator. A magnitude comparison between the input signal and one or more reference signals can be performed. For example, the first comparison module 237 may compare the current signal output by the current sensor 220 with the first reference electrical signal (a reference current, for example, the reference current may be 0 A). When the current signal output by the current sensor 220 is greater than the first reference electrical signal, a first comparison signal is output. When the current signal output by the current sensor 220 is less than or equal to the first reference electrical signal, a second comparison signal is output. Depending on whether the first comparison signal or the second comparison signal is received from the first comparison module 237, the control module 235 can be informed whether the power generation module 200 supplies power to the battery module 240. For example, the first comparison module 237 may be selected to be in a specific type so that the first comparison signal is a high-level signal and the second comparison signal is a low-level signal.

Similarly, the second comparison module 233 may compare the temperature signal output by the temperature sensor 250 with the second reference electrical signal (a reference temperature, for example, the reference temperature may be the first threshold temperature of 5° C. or the second threshold temperature of 15° C.). When the temperature signal output by the temperature sensor 250 is less than the first threshold temperature, a first comparison signal is output. When the temperature signal output by the temperature sensor 250 is greater than or equal to the first threshold temperature and less than the second threshold temperature, a second comparison signal is output. When the temperature signal output by the temperature sensor 250 is greater than the second threshold temperature, a third comparison signal is output. According to whether the first comparison signal, the second comparison signal or the third comparison signal is received from the second comparison module 233, the control module 235 can know whether the battery module 240 needs to be heated. For example, the second comparison module 233 may be selected to be in a specific type so that the first comparison signal is a low-level signal, the second comparison signal is a zero-level signal, and the third comparison signal is a high-level signal. It should be understood that, in an embodiment, the second terminal of the second comparison module 233 may include two ports, and the two ports respectively receive the electrical signal representing the first threshold temperature and the electrical signal representing the second threshold temperature in a one-to-one correspondence.

Specifically, when the control module 235 receives the first comparison signal (which indicates that the current is greater than 0 A) output from the first comparison module 237 and receives a second comparison signal (which indicates that the temperature is greater than or equal to 5° C. and less than 15° C.) output from the second comparison module 233, the control module 235 reduces the output voltage of the power generation module 200 to equal the voltage of the battery module 240, and switches on the switching module 280 to turn on the heating module 260 to heat the battery module 240. When the control module 235 receives the second comparison signal (which indicates that the current is less than or equal to 0 A) output from the first comparison module 237 and receives the first comparison signal (which indicates that the temperature is less than 5° C.) output from the second comparison module 233, the control module 235 increases the output voltage of the power generation module 200 to greater than or equal to the voltage of the battery module 240, and switches on the switching module 280 to turn on the heating module 260 to heat the battery module 240. When the control module 235 receives the first comparison signal (for example, which may be a signal output by the first comparison module 237 when the current is greater than 0 A) output from the first comparison module 237 and receives the second comparison signal (for example, which may be an electrical signal output by the second comparison module 233 when the acquired temperature is greater than or equal to 5° C. and less than 15° C.) output from the second comparison module 233, the control module 235 keeps the current output voltage of the power generation module 200 unchanged, and keeps the current states of the switching module 280 and the heating module 260 unchanged. When the control module receives the second comparison signal (which indicates that the current is less than or equal to 0 A) output from the first comparison module 237 and receives the second comparison signal (which indicates that the temperature is greater than or equal to 5° C. and less than 15° C.) output from the second comparison module 233, the control module 235 increases the output voltage of the power generation module 200 to greater than or equal to the voltage of the battery module 240, and keeps the current states of the switching module 280 and the heating module 260 unchanged. When the control module 235 receives the first comparison signal (which indicates that the current is greater than 0 A) output from the first comparison module 237 and receives the third comparison signal (which indicates that the temperature is greater than 15° C.) output from the second comparison module 233, the control module 235 keeps the output voltage of the power generation module 200 unchanged, and switches off the switching module 280 to make the heating module 260 stop heating. When the control module 235 receives the second comparison signal (which indicates that the current is less than or equal to 0 A) output from the first comparison module 237 and receives the third comparison signal (which indicates that the temperature is greater than 15° C.) output from the second comparison module 233, the control module 235 increases the output voltage of the power generation module 200 to greater than or equal to the voltage of the battery module 240, and switches off the switching module 280 to make the heating module 260 stop heating.

According to the above control logic, the control module 235 can further precisely adjust the output voltage of the power generation module 200 and the on-off time of the heating module 260, thereby avoiding energy waste due to low charging efficiency at a low temperature. It should be noted that, in order to realize the above control logic, the control module 235 can combine the high and low level signals output by the comparison modules in the embodiment based on a logic device, and connect the output terminal of each comparison module to an input terminal of a selector respectively. For example, when there are three comparison modules, a three-to-eight decoder can be selected, and then each output port of the decoder is connected to a different PWM wave generator respectively. According to the change of the high and low levels output by the comparison module, the output of PWM waves with different duty ratios is realized, and the PWM waves control the on-off of the controlled device in the power generation module, thereby changing the output voltage of the power generation module. As can be seen, the charging system provided in the present application can be implemented in hardware without relying on an improvement in a software method.

In an embodiment, as shown in FIG. 4, the control module 235 includes a voltage adjustment module 2354 and a heating control module 2352. A first terminal of the voltage adjustment module 2354 is connected to the third terminal of the power generation module 200, a first terminal of the heating control module 2352 is connected to the third terminal of the first comparison module 237, a second terminal of the heating control module 2352 is connected to the third terminal of the second comparison module 233, a third terminal of the heating control module 2352 is connected to a second terminal of the voltage adjustment module 2354, and a fourth terminal of the heating control module 2352 is connected to the third terminal of the switching module 280.

Specifically, the heating control module 2352 is configured to receive the comparison signals output by the first comparison module 237 and the second comparison module 233 in the above-mentioned embodiment, and output the corresponding voltage adjustment signals (including a voltage increasing signal and a voltage decreasing signal) and a switch on-off signal according to the control logic of the above-mentioned embodiment. The voltage adjustment module 2354 is configured to receive the voltage adjustment signal output from the above heating control module 2352 to control the adjustment of the output voltage of the power generation module 200.

Through the independent transmission of the voltage adjustment signal and the heating control signal, the rapid adjustment of the output voltage of the power generation module 200 and the rapid on-off control of the heating module 260 are realized.

In an embodiment, the heating module 260 is a positive temperature coefficient (PTC) heating plate. PTC is a typical temperature-sensitive semiconductor resistor. When the temperature of the PTC exceeds a certain temperature (e.g., Curie temperature), the resistance of the PCT increases stepwise with the increase of the temperature, and no heat is generated at this time. The above-mentioned PTC heating plate includes but is not limited to ceramic PTC resistor and organic polymer PTC resistor. Using the above heating resistor to heat the battery module 240, when the temperature of the heating module 260 exceeds a safe temperature (e.g., 70° C.), the heating module 260 can be turned off without the control of the battery management system 230, thereby further improving the reliability of the battery module 240.

In an embodiment, as shown in FIG. 6, the heating module 260 completely covers one of end faces of the battery module 240. Specifically, the battery module 240 is provided with a heat-conducting plate on one side. In this embodiment, the heating module 260 is in direct contact with the heat-conducting plate, so that when the heating module 260 is activated, the generated heat can be transferred to a battery cell through the heat-conducting plate, so as to realize the heating of the battery module 240. Generally, in the absence of the heating module 260, the temperature of a position close to the outside of the casing of the battery module 240 is lower than the temperature of a position close to the center of the casing of the battery module 240. In this embodiment, the temperature of the surface and interior of the battery module 240 can be increased by heating the battery module 240 with the heating module 260, thereby reducing the temperature difference between the battery module 240 and its parts.

In an embodiment, the current sensor 220 includes a shunt. Specifically, as shown in FIG. 1, the shunt is disposed between the battery module 240 and the power generation module 200, and the shunt is configured to measure the current between the battery module 240 and the power generation module 200. The shunt can be a resistor with a small resistance, and when a DC current flows through it, a voltage drop is generated, and a signal is then transmitted to the battery management system 230.

In an embodiment, the battery module 240 includes a lithium battery, and the lithium battery is a type of battery that uses lithium metal or lithium alloy as the positive/negative electrode material and uses a non-aqueous electrolyte solution. This type of battery is small in size and large in capacity, and the use of this type of battery can better realize the miniaturization of the module.

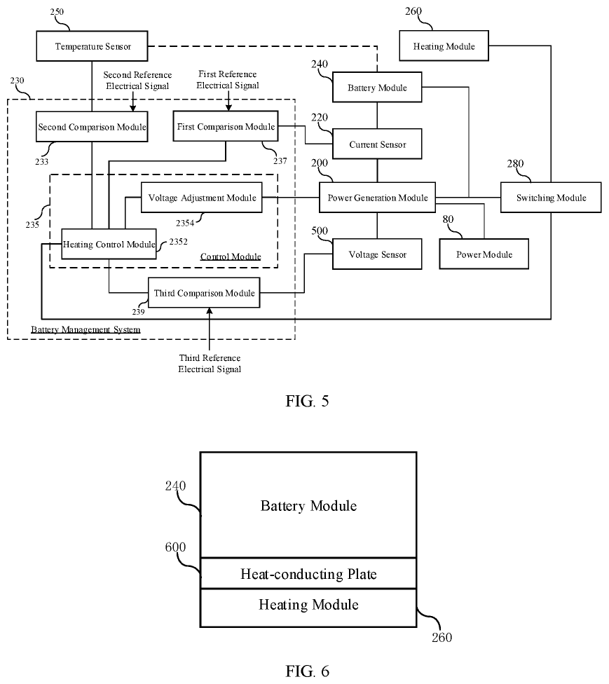

In an embodiment, as shown in FIG. 5, the battery low-temperature heating and charging system 100 further includes a voltage sensor 500, and the battery management system 230 further includes a third comparison module 239. A first terminal of the voltage sensor 500 is connected to the fourth terminal of the power generation module 200, a first terminal of the third comparison module 239 is connected to a second terminal of the voltage sensor 500, a second terminal of the third comparison module 239 is connected to a fifth terminal of the heating control module 2352, and a third terminal of the third comparison module 239 is configured to receive a third reference electrical signal. The third reference electrical signal is an electrical signal representing a threshold voltage.

The third comparison module 239 may be a voltage comparator. A magnitude comparison between the input signal and one or more reference signals can be performed. For example, the third comparison module 239 may compare the voltage signal output by the voltage sensor 500 with the first reference electrical signal (i.e., a reference voltage, which may be for example, 48V). When the voltage signal output by the voltage sensor 500 is greater than the first reference electrical signal, a first comparison signal is output. When the voltage signal output by the voltage sensor 500 is less than or equal to the first reference electrical signal, a second comparison signal is output. Depending on whether the first comparison signal or the second comparison signal is received from the third comparison module 239, the control module 235 can be informed whether the power generation module 200 supplies power to the battery module 240. For example, the third comparison module 239 may be selected to be in a specific type so that the first comparison signal is a high-level signal and the second comparison signal is a low-level signal.

The heating control module 2352 and the voltage adjustment module 2354 adjust the output voltage of the power generation module 200 to below the battery voltage according to the signal output by the third comparison module 239, so as to prevent the battery module 240 from being charged before reaching the charging temperature, thereby avoiding the energy waste caused by low charging efficiency of the battery module 240 at a low temperature.

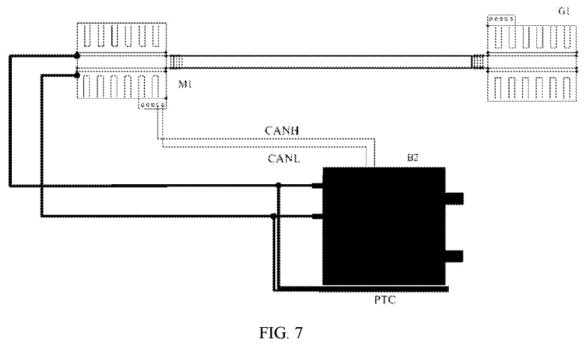

In order to further explain the present application, the following description will be given with reference to a specific example, which takes the low-temperature charging of a lithium battery as an example. In this case, as shown in FIG. 7, the power generation module 200 is a generator M1, the power module 80 is an engine G1, the battery module 240 is a lithium battery B2, and the heating module 260 is a PTC heating plate. The generator M1 is respectively connected to the engine G1 and the lithium battery B2, and the PTC heating plate is respectively connected to the lithium battery B2 and the generator M1. The PTC heating plate completely covers one of the end surfaces of the lithium battery B2.

When the vehicle starts, the engine G1 drives the generator M1 to generate electric power through the belt. The battery management system (BMS) 230 detects the current temperature of the lithium battery B2, and when the cell temperature of the lithium battery B2 meets the charging requirements, the lithium battery B2 is charged normally. When the battery management system detects that the temperature of the lithium battery B2 is too low (for example, below 5° C.), the lithium battery B2 will not be charged. The lithium battery B2 sends an output voltage request signal to the generator M1 through a CAN bus (including CANH and CANL). At this time, the voltage output by the generator M1 is slightly lower than the current voltage of the lithium battery B2, and the heating switch of the PTC heating plate is switched on. At this time, the lithium battery B2 supplies power to the PTC heating plate for heating, and during the above heating process, the battery management system 230 continuously detects the voltage of the generator M1 and the discharge of the lithium battery B2 to the generator M1 or the PTC heating plate. Before the cell temperature of the lithium battery B2 reaches 5° C., the lithium battery B2 sends a voltage adjustment signal to the battery management system 230 through the CAN bus, and then the battery management system 230 adjusts the output voltage of the generator M1. The output voltage is always less than or equal to the voltage of the lithium battery B2. When the output voltage of the generator M1 is equal to the voltage of the lithium battery B2, the generator M1 and the lithium battery B2 supply power to the PTC heating plate for heating at the same time. With the dynamic change of the power during the heating process of the PTC heating plate, the battery management system 230 adjusts the output voltage of the generator M1 in real time, samples the current of the lithium battery B2 through the shunt in the process, and always adjusts the voltage of the generator M1 to keep the sampled current in the lithium battery B2 as 0. When the cell temperature of the lithium battery B2 reaches 5° C. or higher, the battery management system 230 continues to adjust the output voltage of the generator M1, and charges the lithium battery B2 according to the battery temperature and the charging current curve. When the temperature of the lithium battery B2 is greater than 15° C., the PTC heating plate is turned off. Before the battery of the lithium battery B2 is fully charged, the battery management system 230 will determine whether the heating circuit needs to be turned on when charging the battery according to the temperature of the lithium battery B2 until the battery is fully charged. Through the adjustment of the PTC heating plate and the generator M1 by the above-mentioned battery management system 230, the output voltage of the generator M1 can be adjusted in real time, and whether the heating circuit needs to be turned on when charging the battery is determined according to the temperature of the lithium battery B2, which provides a multi-scenario adaptation for the battery charging, thereby avoiding the energy waste caused by the low charging efficiency of the battery in the low temperature scene, and avoiding the safety issue caused by the battery fire due to the high temperature in the high temperature scene.

In an embodiment, the temperature of the battery module 240 may refer to the cell temperature of the battery module 240, so as to improve the control accuracy of the battery low-temperature heating and charging system.

In an embodiment, as shown in FIG. 1, a vehicle-mounted air conditioning system is provided, including an air conditioner body mounted on a vehicle body. The vehicle-mounted air conditioning system further includes the above-mentioned battery low-temperature heating and charging system 100. The battery low-temperature heating and charging system 100 is mounted on the vehicle body, and the battery module 240 is connected to the air conditioner body.

For the understanding of the battery low-temperature heating and charging system 100, reference can be made to the description in the above embodiments. The vehicle-mounted air conditioning system provided in the embodiment of the present application can ensure that the kinetic energy of the power module 80 is converted into electrical energy to the maximum extent effectively during the driving process of the vehicle by equipping the above-mentioned battery low-temperature heating and charging system 100, so as to supply power to the vehicle-mounted air conditioner 120, thus ensuring the stability and reliability of the power supply of the vehicle-mounted air conditioner 120, improving energy utilization, and environmental protection and energy saving. In addition, since the utilization efficiency of the mechanical energy of the power module 80 is improved, the frequency of use of the backup power supply for power supply guarantee of the vehicle-mounted air conditioner 120 can be reduced, and the service life of the backup power supply can be improved. The air conditioner body is used for cooling and/or heating, and the selection of its cooling and heating modes can be based on the actual needs of the user.

In an embodiment, as shown in FIG. 1, a vehicle is provided, which includes a vehicle body, and the vehicle body is equipped with the power module 80. The vehicle also includes the battery low-temperature heating and charging system 100 mounted on the vehicle body.

Specifically, the battery low-temperature heating and charging system 100 is connected to the power module 80. When the vehicle starts, the power module 80 provides the battery low-temperature heating and charging system 100 with energy, and the battery low-temperature heating and charging system 100 converts the kinetic energy of the power module 80 into electrical energy, which is stored in the system, and supplies power to other external devices (such as the vehicle-mounted air conditioner 120).

In the description of this specification, reference to the description of the terms “some embodiments”, “other embodiments”, “ideal embodiments”, etc. means that a particular feature, structure, material or feature described in connection with the embodiment or example is included in the present specification at least an embodiment or example of the application. In this specification, schematic descriptions of the above terms do not necessarily refer to the same embodiment or example.

The technical features in the above embodiments can be combined arbitrarily. For concise description, not all possible combinations of the technical features in the above embodiments are described. However, all the combinations of the technical features are to be considered as falling within the scope described in this specification provided that they do not conflict with each other.

The above-mentioned embodiments only describe several implementations of the present application, and their description is specific and detailed, but should not be understood as a limitation on the patent scope of the invention. It should be pointed out that for those skilled in the art may further make variations and improvements without departing from the conception of the present application, and these all fall within the protection scope of the present application. Therefore, the protection scope of the present application should be subject to the appended claims.

What is claimed is:

1. A battery low-temperature heating and charging system, comprising:
a heating module;
a switching module having a first terminal connected to the heating module;
a battery module disposed close to the heating module, and having a first terminal connected to a second terminal of the switching module;
a power generation module having a first terminal connected to the second terminal of the switching module;
a temperature sensor configured to acquire a temperature of the battery module;
a current sensor having a first terminal connected to a second terminal of the power generation module, and a second terminal connected to a second terminal of the battery module, the current sensor being configured to detect current supplied from the power generation module to the battery module; and
a battery management system having a first terminal connected to a third terminal of the power generation module, a second terminal connected to a third terminal of the current sensor, a third terminal connected to the temperature sensor, and a fourth terminal connected to a third terminal of the switching module;
wherein the power generation module has a fourth terminal configured to connect a power module.

2. The battery low-temperature heating and charging system according to claim 1, wherein the battery management system comprises:
a first comparison module having a first terminal connected to the third terminal of the current sensor, and a second terminal configured to receive a first reference electrical signal used as an electrical signal representing a threshold current;
a second comparison module having a first terminal connected to the temperature sensor, and a second terminal configured to receive a second reference electrical signal used as an electrical signal representing a first threshold temperature or a second threshold temperature; and
a control module having a first terminal connected to a third terminal of the first comparison module, a second terminal connected to a third terminal of the second comparison module, a third terminal connected to the third terminal of the power generation module, and a fourth terminal connected to the third terminal of the switching module.

3. The battery low-temperature heating and charging system according to claim 2, wherein the control module comprises:
a voltage adjustment module having a first terminal connected to the third terminal of the power generation module; and
a heating control module having a first terminal connected to the third terminal of the first comparison module, a second terminal connected to the third terminal of the second comparison module, a third terminal connected to a second terminal of the voltage adjustment module, and a fourth terminal connected to the third terminal of the switching module.

4. The battery low-temperature heating and charging system according to claim 1, wherein the heating module includes a PTC heating plate.

5. The battery low-temperature heating and charging system according to claim 1, wherein the heating module completely covers at least one end face of the battery module.

6. The battery low-temperature heating and charging system according to claim 1, wherein the current sensor includes a shunt.

7. The battery low-temperature heating and charging system according to claim 1, wherein the battery module includes a lithium battery.

8. The battery low-temperature heating and charging system according to claim 2, further comprising:
a voltage sensor having a first terminal connected to the fourth terminal of the power generation module;
wherein the battery management system further comprises a third comparison module having a first terminal connected to a second terminal of the voltage sensor, a second terminal connected to a fifth terminal of the control module, and a third terminal configured to receive a third reference electrical signal used as an electrical signal representing a threshold voltage.

9. A vehicle-mounted air conditioning system, the vehicle-mounted air conditioning system comprising:
an air conditioner body mounted on a vehicle body; and
the battery low-temperature heating and charging system according to claim 1, mounted on the vehicle body, the battery module being connected to the air conditioner body.

10. A vehicle, the vehicle comprising:
a vehicle body equipped with a power module; and
the battery low-temperature heating and charging system according to claim 1, mounted on the vehicle body.
